(19) United States
(12) Patent Application Publication
(10) Pub. No.: US 2010/0164765 A1
(43) Pub. Date: Jul. 1, 2010

(54) DAC calibration circuits and methods

(76) Inventors: Masaya Miyahara, Chiba (JP); Hasnain Lakdawala, Beaverton, OR (US)

Correspondence Address: INTEL CORPORATION;c/o CPA Global, P.O. BOX 52050, MINNEAPOLIS, MN, 55402, US

(21) Appl. No.: 12/319,090

(22) Filed: Dec. 31, 2008

(51) Int. Cl. H03M 3/00; H03M 1/66; H03M 1/10

(52) U.S. Cl. 341/120; 341/144; 341/143

(57) ABSTRACT

Provided is a DAC with tuning circuitry in accordance with some embodiments for tuning current sources in the DAC. The DAC may be used for a sigma-delta converter in some embodiments.

### BACKGROUND

The present invention relates generally to digital to analog converter circuits.

FIG. 1A shows a portion of a conventional sigma-delta (ΣΔ) modulation based conversion block to convert an N-bit digital signal into an analog signal Vout. It comprises a digital ΣΔ modulator 102 and a digital-to-analog (DAC) block 103. The digital ΣΔ circuit 102 converts a larger N bits (lower frequency) word into a smaller M bits (higher frequency) word. (For example, N could correspond to a 12 bit word and M could correspond to a 3 bit word.) The DAC block 103 converts the M bit signal into an analog version (Vout) of the same. The DAC block 103 comprises a digitally controlled current sources block 104 with a calibration section 105 and a filter/amplifier 106, coupled as shown. (For simplicity, clock and other signals may not be shown.) The calibration section 105 is used to calibrate the current sources that make up the DCI 104. This aspect may be important, especially with ΣΔ conversion applications.

FIG. 1B shows a conventional DCI section, e.g., for DCI block 104. In this example, there are k current sources (I₁ to Iₖ), along with a reference source (Iref). Each of these sources controllably feeds into a differential output (Vout′). Each of the bit sources (I₁ to Iₖ) also has an associated calibration source (I_{1cal} to I_{kcal}, respectively) for calibrating its associated current source so that the current from each bit source node is the same. It includes a decoder 111 to decode the M bit word into the 2^{M} (I₁ to Iₖ bits)+1 (Iref bit) switches to control the current source switches (S) so that the currents feed into either the positive (+) or negative (−) rail of the output. (The reference source, Iref, may or may not be included in different implementations. It can be used to compensate for offset errors and also can be used as the standard for calibrating the different bit currents.)

Unfortunately, with voltage scaling and other circumstances, it is becoming more difficult to design a high accuracy digital-to-analog converter (DAC) using standard techniques. Even though there are calibration sources for tuning the bit sources with each other, it is difficult to accurately measure and tune them against each other. Accordingly, new approaches for tuning the current sources would be desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1A is a diagram of a portion of a conventional sigma-delta converter.

FIG. 1B is a diagram of digitally controlled current sources for a DAC block in the sigma-delta converter of FIG. 1A.

FIG. 2 is a diagram of a portion of a sigma-delta conversion block with a new tuning circuit in accordance with some embodiments.

FIG. 3 is a diagram of the calibration aspect of the tuning circuit for the tuning circuit of FIG. 2.

FIG. 4 is a block diagram of a computer system having a wireless interface with at least one transmitter with a sigma-delta conversion block and tuning circuitry in accordance with some embodiments.

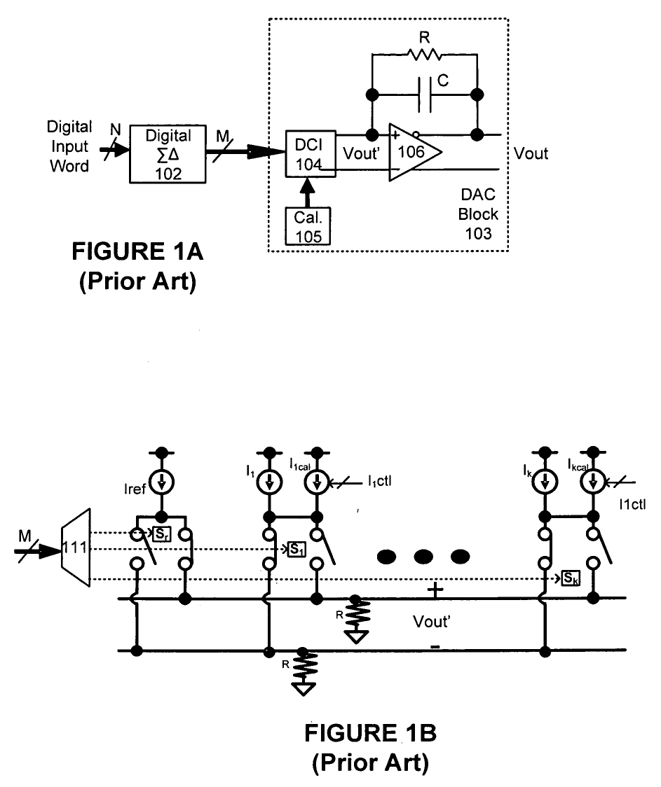

### DETAILED DESCRIPTION

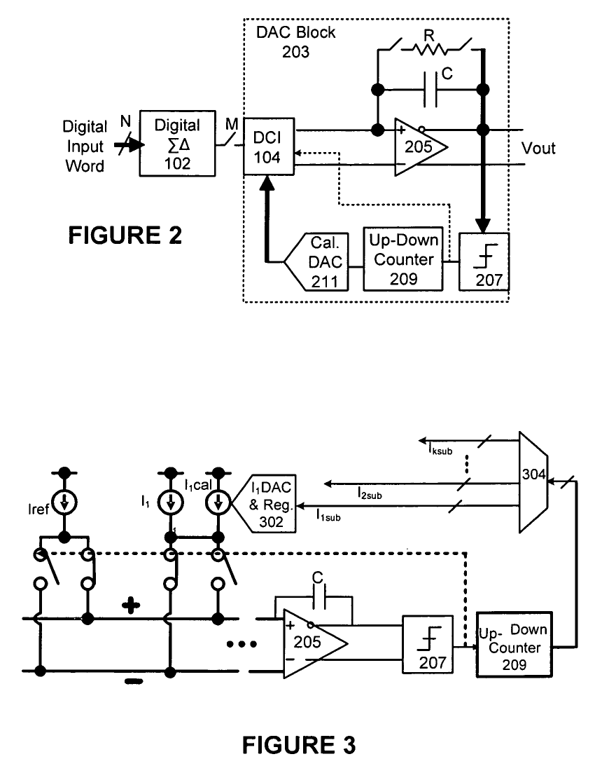

FIG. 2 shows a portion of a sigma-delta conversion block in accordance with some embodiments. It comprises a DAC block 203 with tuning circuitry in accordance with some embodiments for tuning the current sources in the DAC. In the depicted embodiment, the tuning circuitry comprises a comparator (or digitizer) 207, an up/down counter 209, and a calibration DAC 211 (which is incorporated into or already part of the DCI 104). The tuning portion also uses the filter 205, but with the resistor R switched out so that it functions as an integrator.

The components are coupled as shown, making a closed proportional integrator loop for zeroing out error between the various bit sources in the DCI 104. (For simplicity, control circuitry for controlling the tuning circuitry to separately tune different pairs of current sources is not shown since it is fairly trivial and may be done in various different ways. For example, separate dedicated logic could be included or a separate controller, e.g., for controlling different start-up or calibration functions in a transmitter or radio containing the sigma-delta digital to analog converter could be used.) A benefit of some embodiments in accordance with the depicted figure is that the integrator is derived from the filter already in the DAC block, i.e., a separate integrator circuit is not necessarily required.

In operation, during a calibration mode (e.g., when the transmitter containing the converter is idle or at start-up), the resistor R in the filter is switched out so that filter/integrator 205 functions as an integrator (as opposed to a filter when in conversion operation mode). Each bit source in the DCI 104 is then tuned so that the bit sources are suitably equivalent with one another. The DCI 104 is controlled so that current source pairs, the source to be tuned and a reference source (which may be one of the bit sources or a separate reference source as is the case in the figure), are separately tuned, one pair at a time. The cal DAC 211 actually comprises a separate calibration DAC for each source that is to be tuned. So, during calibration, when a source is to be tuned, it is subtractively fed into the integrator against the source used as the reference. Any difference (or error between them) is integrated and fed to the comparator, which controls the counter to go up or down, depending on the error direction and amount. This causes the calibration DAC for the source being tuned to go up or down accordingly until the loop converges to an error sufficiently approaching zero. (In the depicted embodiment, with a counter, the up-down counter will lock at an offset cancellation value.)

FIG. 3 shows the current sources of the DCI 104 and the tuning loop components in greater detail. Note that current sources ar shown for a reference source and the first source (I₁)k, the others are omitted for clarity. Likewise, a calibration DAC (I₁DAC) for the first bit source is shown, but the others would also have separate calibration DACs and in this embodiment, their calibration DACs would also comprise a separate register for storing the tuned DAC value for the bit. In this embodiment, a reference source (Iref) is included, but this could be omitted in other embodiments.

In some embodiments, the comparator 207 may also be used to control the current sources so that their directions correspond to whether or not the comparator output is high or low. This is represented with a dashed line in both FIGS. 2 and 3. When the comparator 207 is high the switches are connected such that the net current is in one direction and if the comparator output 207 is low the switches are connected in the opposite manner. This is done to maintain the average loop value at or approaching zero once compared sources suitably converge, as discussed in the next section.

During calibration, each bit source is separately tuned against the reference source. So, when the first bit source is tuned, as shown in the figure, The switches for the reference source and the bit source are controlled so that the currents are oppositely fed into the differential input of the integrator 205. Their difference is then integrated at 205 and compared (e.g., against a zero reference) at comparator 207. If the currents of the reference and the bit source are the same then the average value of the comparator output should be zero. If average output is non-zero then the current sources are not the same. Its DAC is selected through word multiplexer 304, so the counter controls its calibration DAC (I1DAC for the I₁) to add or take away current from the bit source (I₁) depending on the error between I₁ and Iref. (It is actually adding or removing a correction current from the common node, but for simplicity, this node will be referred to as I₁ or the like. Along these lines, in other embodiments, an adjustable current source could be used instead of separate sources, depending on design considerations.)

The proportional integral (PI) control loop causes the counter to control the calibration DAC until the difference of the sources being compared sufficiently approaches zero. In most cases, this will occur in less than the number of cycles corresponding to twice the counter's number of counts. This process is then repeated for the other bit sources to be calibrated (or tuned).

In most cases, the offsets of the opamp in the filter are not important. However in some applications, if this becomes important. it can be corrected in various ways. One way, for example, would be to change the polarity of the comparator output and run the calibration loop. The difference in the two calibration values cold then be used to calibrate the DAC current source. The offset of the comparator can also be corrected using well known techniques like correlated double sampling or chopping. In addition, depending on design considerations, the calibration DACs and thus the counter as well should have sufficient resolution to cover for the needed resolution and accuracy of the DCI. For example, in some embodiments, a 4 or 5 bit counter with 4 or 5 bit calibration DACs may be used.

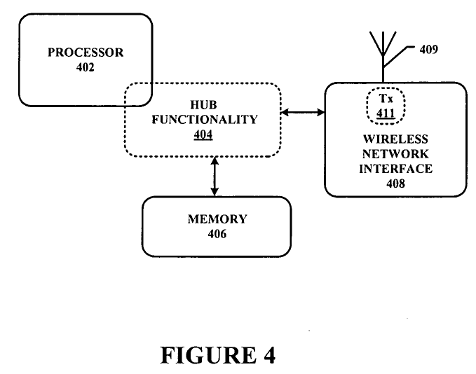

With reference to FIG. 4, one example of a portion of a computer platform (e.g., computing system such as a mobile personal computer, PDA, cell phone, or the like) is shown. The represented portion comprises a processor 402, hub (interface control) functionality 404, memory 406, wireless network interface 408 (having a transmitter 411 which comprises a sigma-delta conversion block with a tuning circuit as discussed herein), and an antenna 409. The processor 402 is coupled to the memory 406 and wireless network interface 408 through the hub functionality 404. The hub functionality may comprise one or more circuit blocks to perform various interface control functions (e.g., memory control, graphics control, I/O interface control, and the like. These circuits may be implemented on one or more separate chips and/or may be partially or wholly implemented within the processor(s) 402.

The memory 406 comprises one or more memory blocks to provide additional random access memory to the processor(s) 402. it may be implemented with any suitable memory including but not limited to dynamic random access memory, static random access memory, flash memory, or the like. The wireless network interface 408 is coupled to the antenna 409 to wirelessly couple the processor(s) 402 to a wireless network (not shown) such as a wireless local area network or a cellular network.

The platform may implement a variety of different computing devices or other appliances with computing capability. Such devices include but are not limited to laptop computers, notebook computers, personal digital assistant devices (PDAs), cellular phones, audio and/or or video media players, and the like. It could constitute one or more complete computing systems or alternatively, it could constitute one or more components useful within a computing system.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, material types, insulator thicknesses, gate(s) configurations, to mention just a few. Moreover, unless specifically referred to as MOS or the like, the term transistor can include other suitable transistor types, e.g., junction-field-effect transistors, bipolar-junction transistors, metal semiconductor FETs, and various types of three dimensional transistors, MOS or otherwise, known today or not yet developed.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS., for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a digital to analog converter having current sources; and
a tuning circuit having an integrator to form an integral feedback loop to tune the current sources to reduce the errors between them.

2. The chip of claim 1, in which all of the current sources are to be suitably equivalent to each other.

3. The chip of claim 1 wherein the integrator is derived from a filter that is to be used with the DAC in a non-tuning mode.

4. The chip of claim 1, in which the tuning circuit comprises a low pass digital filter to be part of the integral feedback loop.

5. The chip of claim 4, in which the low pass filter comprises an up-down counter.

6. The chip of claim 1, in which the tuning circuit comprises a separate register to store a tuned value for a separate calibration DAC for each source to be tuned.

7. The chip of claim 1, in which the DAC is part of a sigma-delta converter circuit.

8. The chip of claim 1, in which the tuning circuit is formed from at least part of a sigma-delta analog to digital converter circuit.

9. The chip of claim 1, in which the DAC comprises equally weighted current sources for each bit source.

10. A method, comprising:
tuning a first and a second current source in a sigma-delta converter DAC by adjusting the current for one of the first and second sources in response to zeroing the error between the sources using a proportional integral feedback loop.

11. The method of claim 10, in which adjusting comprises adjusting the current in a parallel source to the source being adjusted.

12. The method of claim 10, in which adjusting comprises adjusting the source to be adjusted.

13. The method of claim 10, comprising switching out one or more circuit elements from a filter to derive an integrator to create the proportional integral feedback loop.

14. The method of claim 10, comprising controlling source current direction based on an output from a comparator.

15. A system, comprising:
a host processor; and
a wireless interface card having a transmitter, the transmitter including a sigma-delta converter including a digital to analog converter having current sources, and a tuning circuit having an integrator to form an integral feedback loop to tune the current sources to reduce the errors between them.

16. The system of claim 15, comprising an antenna to provide a radio signal to the transmitter.

17. The system of claim 15, in which all of the current sources are to be suitably equivalent to each other.

18. The system of claim 15, wherein the integrator is derived from a filter that is to be used with the DAC in a non-tuning mode.

19. The system of claim 15, in which the tuning circuit comprises a low pass digital filter to be part of the integral feedback loop.
